(19) United States
(12) Patent Application Publication
(10) Pub. No.: US 2024/0423057 A1
(43) Pub. Date: Dec. 19, 2024

(54) DISPLAY PANEL

(71) Applicant: KUNSHAN GO-VISIONOX OPTO-ELECTRONICS CO., LTD., Kunshan (CN)

(72) Inventors: Chao Chi PENG, Kunshan (CN); Deqiang ZHANG, Kunshan (CN); Mingxing LIU, Kunshan (CN); Zhe LI, Kunshan (CN); Yahong LIU, Kunshan (CN)

(73) Assignee: KUNSHAN GO-VISIONOX OPTO-ELECTRONICS CO., LTD., Kunshan (CN)

(21) Appl. No.: 18/817,245

(22) Filed: Aug. 28, 2024

Related U.S. Application Data
(63) Continuation of application No. PCT/CN2024/082343, filed on Mar. 19, 2024.

(30) Foreign Application Priority Data
Jul. 24, 2023 (CN) 202310909421.5

(51) Int. Cl. H10K 59/35; H10K 59/131; H10K 59/80

(52) U.S. Cl. CPC H10K 59/353; H10K 59/131; H10K 59/80515

(57) ABSTRACT

Disclosed is a display panel, including a plurality of pixel units. Each pixel unit includes a plurality of sub-pixels. The plurality of sub-pixels include a first sub-pixel, a second sub-pixel, and a third sub-pixel disposed sequentially from inside to outside. A centroid of the pixel unit is located in the first sub-pixel, and at least one of the second sub-pixel and the third sub-pixel is a non-closed ring including at least one gap to communicate an inner side and an outer side of the second sub-pixel and/or the third sub-pixel. In this design, a roughly uniform distribution of sub-pixels relative to the centroid of the pixel unit. Thus, uniformity of light emission is improved, thereby improving display effect. In addition, a voltage drop difference between an inner and an outer pixel units during driving may be reduced through the opening, thereby avoiding excessive voltage drop of inner sub-pixels.

### CROSS-REFERENCE TO RELATED APPLICATIONS

This application is a continuation of International Application No. PCT/CN2024/082343, filed on Mar. 19, 2024, which claims priority to Chinese Patent Application No. 202310909421.5, filed on Jul. 24, 2023. Both of the aforementioned applications are hereby incorporated by reference in their entireties.

### TECHNICAL FIELD

Embodiments of the present disclosure relate to the field of display technologies, and in particular, to a display panel.

### BACKGROUND

An organic light-emitting diode (OLED) is an organic thin-film electroluminescent device. Due to advantages of simple preparation process, low cost, low power consumption, high brightness, wide viewing angles, high contrast, and the ability to achieve flexible displays, the organic light-emitting diode device has attracted significant attention and is widely used in electronic display products.

However, currently, electronic display products are limited to a design of their own structure, making it difficult to further improve uniformity of light emitted by pixels, thus unable to further meet requirements of users.

### SUMMARY

A first aspect of the present disclosure provides a display panel, and the display panel includes a plurality of pixel units. Each of the plurality of pixel units includes a plurality of sub-pixels emitting light of different colors. In each of the plurality of pixel units, the plurality of sub pixels are arranged in sequence from inside to outside. A centroid of the pixel unit is located in an innermost sub pixel, and at least one of the sub-pixels located on an outer side of the innermost sub pixel is configured to be a non closed ring with at least one gap. The gap communicates with the inner side and the outer side of the sub pixel. For example, the plurality of sub-pixels of each of the plurality of pixel units include a first sub-pixel, a second sub-pixel, and a third sub-pixel disposed sequentially from inside to outside and respectively in a surrounding manner, and a centroid of the pixel unit is located in the first sub-pixel. At least one of the second sub-pixel and the third sub-pixel is configured to be a non-closed ring with at least one gap. The gap communicates with an inner side and an outer side of the at least one of the second sub-pixel and the third sub-pixel.

A second aspect of the present disclosure provides a display panel, and the display panel includes a substrate and an isolation structure located on the substrate. The isolation structure includes a plurality of opening groups, and each of the plurality of opening groups includes a plurality of first openings. In each of the plurality of opening groups, a centroid of the opening group is located in an innermost first opening. The first openings are disposed sequentially from inside to outside, and at least one of the first openings located on an outer side of the innermost first opening is a non-closed ring with a gap.

A third aspect of the present disclosure provides a display panel, and the display panel includes a substrate and a plurality of first electrodes located on the substrate. The plurality of first electrodes are divided into a plurality of electrode groups, and each electrode group includes a plurality of first electrodes. In each of the plurality of electrode groups, a centroid of the electrode group is located in an innermost first electrode, the first electrodes are disposed sequentially from inside to outside, and the first electrodes located on an outer side of the an innermost first electrode are closed rings.

### BRIEF DESCRIPTION OF THE DRAWINGS

FIG. 1 is a planar schematic structural diagram of a display panel according to an embodiment of the present disclosure.

FIG. 2 is an enlarged view of the S1 region shown in FIG. 1 illustrating a plurality of pixel units.

FIG. 3 is a planar schematic structural diagram of a pixel unit of the display panel shown in FIG. 2.

FIG. 4 is a planar schematic structural diagram of an isolation structure corresponding to the pixel unit shown in FIG. 2 illustrating a plurality of opening groups.

FIG. 5 is a planar schematic structural diagram of a part of the isolation structure shown in FIG. 3 corresponding to a pixel unit.

FIG. 6 is a planar schematic structural diagram of a first electrode corresponding to the pixel unit shown in FIG. 2 illustrating a plurality of electrode groups.

FIG. 7 is a planar schematic structural diagram of a first electrode of the electrode group shown in FIG. 6 corresponding to a pixel unit.

FIG. 8 is a cross-sectional view of the pixel unit along M1-N1 shown in FIG. 3.

FIG. 9 is a planar schematic structural diagram of another sub-pixel of a display panel according to an embodiment of the present disclosure.

FIG. 10 is a planar schematic structural diagram of an isolation structure corresponding to the pixel unit shown in FIG. 9.

FIG. 11 is a planar schematic structural diagram of another pixel unit of a display panel according to an embodiment of the present disclosure.

FIG. 12 is a planar schematic structural diagram of still another pixel unit of a display panel according to an embodiment of the present disclosure.

FIG. 13 is a planar schematic structural diagram of yet still another pixel unit of a display panel according to an embodiment of the present disclosure.

FIG. 14 is a cross-sectional view of a partial region of a display panel according to an embodiment of the present disclosure.

FIGS. 15A to 15D are schematic diagrams of a preparation method of a display panel according to an embodiment of the present disclosure.

### DETAILED DESCRIPTION OF THE EMBODIMENTS

Layout of pixels of a display panel may affect display effect in a display area. Each pixel (also known as a large pixel) is provided with a plurality of sub-pixels (also known as micro-pixels) to emit light of any color and brightness. The light is a combination of light emitted from different sub-pixels. However, currently, sub-pixels may have a significant offset from a center position (such as a centroid) of the pixel as limited by its own structural design, and the offset degree of different sub-pixels is not consistent, resulting in light emitted from each sub-pixel not being uniformly distributed relative to the center of the pixel. Therefore, visual effect of the display panel may not be further improved. For example, in specific viewing angles such as a large viewing angle, as the brightness decreases, the human eye will be more likely to distinguish differences of colors, resulting in severe color deviation in the visual effect of the display area.

In an embodiment of the present disclosure, in each pixel unit, sub-pixels emitting light of different colors are disposed sequentially from inside to outside, so that a centroid of the sub-pixel tends to coincide with a centroid of the pixel unit. Thus, the light emitted by the sub-pixels may be uniformly distributed relative to the centroid of the pixel unit, thereby solving the problem mentioned above.

In addition, according to the design mentioned above, if the sub-pixels are presented in a circular shape, the inner sub-pixels will be completely separated from the outer sub-pixels. When the sub-pixels are driven to emit light, there will be a significant voltage drop between adjacent sub-pixels, resulting in a significant difference in the driving voltage (common voltage) of the sub-pixels. Accordingly, the light-emitting brightness (gray scale) of the sub-pixels will be affected, causing the display effect of the display panel to not meet requirements of users.

In at least one embodiment of the present disclosure, a sub-pixel of a pixel unit located on an outer side (except for an innermost sub-pixel) is provided with a gap to present as a non-closed ring, so that the driving current may enter from the gap of the sub-pixel, thereby solving the technical problem mentioned above. The display panel includes a plurality of pixel units. Each pixel unit includes a plurality of sub-pixels emitting light of different colors. The plurality of sub-pixels of each pixel unit are disposed sequentially from inside to outside, and a centroid of the pixel unit is located in an innermost sub-pixel. At least one of the sub-pixels located on an outer side of the innermost sub-pixel is configured to be a non-closed ring with at least one gap, and the gap communicates with an inner side and an outer side of the sub-pixel. In this way, the sub-pixels in each pixel unit are disposed sequentially from inside to outside, which is equivalent to a roughly uniform distribution of sub-pixels relative to the centroid of the pixel unit, to improve the uniformity of light emission and thus improve the display effect. In addition, the voltage drop difference between the inner and outer edges of the pixel unit during driving may be reduced by providing gaps, thereby avoiding excessive voltage drop of inner sub-pixels.

In addition, at least one embodiment of the present disclosure provides a display panel, and the display panel includes a substrate and an isolation structure located on the substrate. The isolation structure includes a plurality of first openings, the plurality of first openings are divided into a plurality of opening groups, and each of the opening groups includes a plurality of first openings. A centroid of each of the plurality of opening groups is located in an innermost first opening, and the first openings are disposed sequentially from inside to outside. At least one of the first openings on an outer side of the innermost first opening is a non-closed ring. The first opening is configured to confine the position of the sub-pixel, that is, the sub-pixel is formed and restricted in the first opening. Therefore, technical effects in the embodiments mentioned above may be achieved, which will not be described herein again.

In addition, at least one embodiment of the present disclosure provides a display panel, and the display panel may include a substrate and a plurality of first electrodes located on the substrate. The first electrodes are divided into a plurality of electrode groups, and each of the electrode groups includes a plurality of first electrodes. A centroid of each of the plurality of electrode groups is located in an innermost first electrode, and the first electrodes are disposed sequentially from inside to outside. The first electrodes located on an outer side of the innermost first electrode are closed rings. Specific positions and shapes of sub-pixels are limited by positions and shapes of the first electrodes. Thus, this design may also ensure that the light emitted from each pixel is uniformly distributed relative to the centroid of the pixel unit (equivalent to the center position) to improve the display effect of the display panel. The term “outer” in the present disclosure refers to positions other than the innermost position.

In the following, a description of a structure of a display panel according to at least one embodiment of the present disclosure will be provided with reference to the accompanying drawings. In these accompanying drawings, a spatial rectangular coordinate system is established based on a plane of the display panel (such as a display surface, equivalent to a surface of the substrate mentioned in subsequent embodiments) to explain positional relationships of various structures of the display panel. In the spatial rectangular coordinate system, the X-axis and Y-axis are parallel to a plane where the display panel is located, and the Z-axis is perpendicular to the plane where the display panel is located.

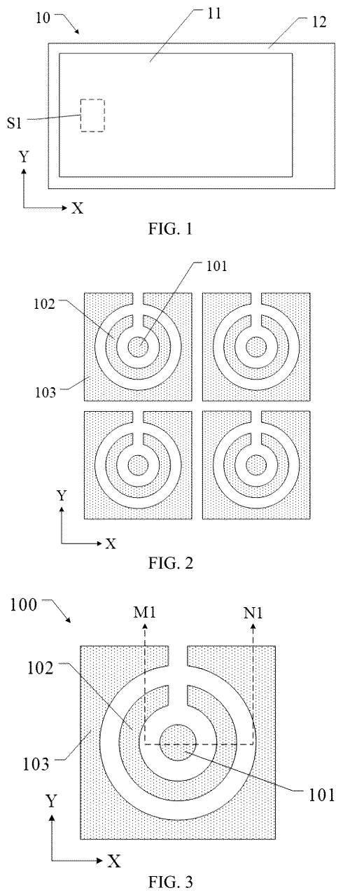

As shown in FIGS. 1 to 3 and FIG. 8, a planar area of the display panel 10 includes a display area 11 and a frame area 12 located on at least one side of the display area 11. A plurality of pixel units 100 are provided in the display area 11, and each of the pixel units 100 includes a plurality of sub-pixels emitting light of different colors, such as a first sub-pixel 101, a second sub-pixel 102, and a third sub-pixel 103. In each of the pixel units 100, the plurality of sub-pixels are disposed sequentially from inside to outside, and a centroid of pixel unit 100 is located in an innermost sub-pixel. At least one of the second sub-pixel and the third sub-pixel is configured to be a non-closed ring with at least one gap. The gap communicates with an inner side and an outer side of the sub-pixel. In this way, the first sub-pixel 101, the second sub-pixel 102, and the third sub-pixel 103 are disposed sequentially from inside to outside. The first sub-pixel 101, the second sub-pixel 102, and the third sub-pixel 103 are roughly uniformly distributed relative to the centroid of the pixel unit 100, thereby improving the uniformity of the light emission of the pixel unit 100 and thus improving the display effect of the display panel 10. In addition, the voltage drop difference between the inner and outer sides of the pixel unit 100 during driving may be reduced by providing openings (that is, the gap), avoiding excessive voltage drop of inner sub-pixels.

In some embodiments of the present disclosure, a quantity of sub-pixels in each pixel unit may be set as three as shown in FIG. 2. For example, the first sub-pixel 101, the second sub-pixel 102, and the third sub-pixel 103 respectively emit red light, green light, and blue light (three of which are three primary colors of light). In other embodiments of the present disclosure, the pixel unit may also include four or more sub-pixels. For example, in addition to the above-mentioned light of three primary colors, additional sub-pixels may emit yellow light, white light, and so on. The quantity and the type of light emission of each pixel unit may be set according to requirements of actual process, and the embodiment of the present disclosure does not limit this.

For example, in at least one embodiment of the present disclosure, as shown in FIGS. 1 to 5 and FIG. 8, the display panel 10 may include a substrate 20 and a display function layer located on the substrate 20. The display function layer includes a plurality of light-emitting devices 120, and the light-emitting devices 120 are the physical structure of the sub-pixels. A sub-pixel may include a light-emitting device 120 (as shown in FIG. 2), or a plurality of light-emitting devices 120 (as shown in FIG. 9, where a light-emitting device is provided in each sub-opening). In a same sub-pixel, first electrodes of the plurality of light-emitting devices 120 may be connected to each other.

The light-emitting device 120 includes a first electrode 121 and a second electrode 122 stacked on the substrate 20, as well as a light-emitting function layer 123 located between the first electrode 121 and the second electrode 122. The light-emitting function layer 123 may include a first function layer 1231, a light-emitting layer 1232, and a second function layer 1233. The first function layer 1231, the light-emitting layer 1232, and the second function layer 1233 are sequentially stacked on the first electrode 121. The first function layer 1231 may include a hole injection layer, a hole transport layer, an electron blocking layer, and so on, and the second function layer 1233 may include an electron injection layer, an electron transport layer, a hole blocking layer, and so on.

For example, the first electrode 121 may be the anode, and the second electrode 122 may be the cathode. In some embodiments of the present disclosure, the cathodes of the sub-pixels may be independently controlled, that is, the cathodes of different sub-pixels are not directly or indirectly electrically connected to each other. For example, the cathodes of the sub-pixels may be connected to external circuits through wiring set respectively, or connected to external circuits through the isolation structure (which may be configured to be wiring including conductive parts) described below. Alternatively, the cathodes of each sub-pixel may be electrically connected to each other as a common electrode. For example, these cathodes may be indirectly connected together through the conductive part of the isolation structure mentioned in the embodiments below, and then connected to an external control circuit (such as a common electrode wire).

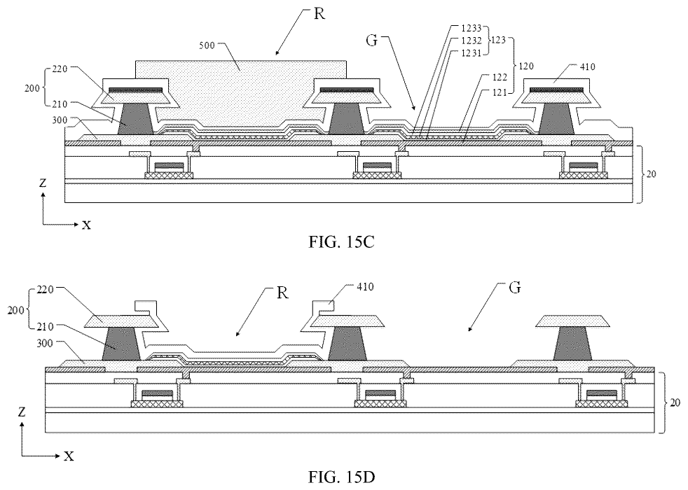

For example, in at least one embodiment of the present disclosure, as shown in FIGS. 1 to 8, the display panel may further include an isolation structure 200 located on the substrate 20. The isolation structure 200 includes a plurality of first openings 201 for respectively defining the sub-pixels (including light-emitting devices 120), the light-emitting function layer 123 of the sub-pixel is located in the corresponding first opening 201, and an orthographic projection of the isolation structure 200 on the substrate 20 is located at intervals and gaps between orthographic projections of the sub-pixels on the substrate 20, that is, the position of the first opening 201 coincides with the position of the sub-pixel. By providing the plurality of first openings 201, the isolation structure 200 is actually in a grid shape. During the preparation process of the light-emitting function layer 123, various film layers of the light-emitting function layer 123 may be vapor deposited as a full surface, but at the edge of the isolation structure 200, due to the presence of segment differences, each film layer in the light-emitting function layer 123 may be disconnected, so that the light-emitting function layer 123 is completely located in the first opening 201. Thus, the preparation of the light-emitting function layer 123 does not require alignment with a mask plate, that is, the problem of alignment accuracy may not exist. Meanwhile, the position of the sub-pixels may be accurately positioned, so that the centroid of the sub-pixels basically coincides with the centroid of the pixel unit 100. As for a principle that a grid-like isolation structure 200 may be used to accurately control the position of the sub-pixels, the related description of embodiments shown in FIGS. 15A to 15D may be referred in the following, and will not be describes herein again.

For example, as shown in FIG. 8, the isolation structure 200 includes a first end 210 facing the substrate 20, and a second end 220 facing away from the substrate 20. An orthographic projection of the first end 210 on the substrate 20 is located within an orthographic projection of the second end 220 on the substrate 20. That is, the shape of the isolation structure 200 is wide at the top and narrow at the bottom, in this way, the isolation effect of the isolation structure 200 on the light-emitting function 123 may be improved. In this case, the first end 210 may be referred to as an isolation column, and the second end 220 may be referred to as a crown.

The first end 210 and the second end 220 of the isolation structure 200 may be a double-layer structure as shown in FIG. 8, or may be a single-layer structure. That is, the first end 210 and the second end 220 may be an integrated structure, which can be designed according to requirements of an actual process, and will not be describes herein again.

For example, as shown in FIG. 8, the second electrode 122 of the sub-pixel is located in the corresponding first opening 201. The second electrode 122 is connected to the first end 210, and the first end 210 is a conductive structure, that is, the second electrode 122 and the first end 210 form a common electrode.

A thickness of the second electrode 122 is configured to be as thin as possible to ensure sufficient transmittance, which also results in a larger square resistance of the second electrode 122, and a significant voltage drop when driving the second electrode 122, thereby impacting the grayscale control of the sub-pixels. In the embodiment of the present disclosure, the isolation structure 200 may be set with a sufficient height to limit the position of the light-emitting device. Therefore, in a case where at least a part of the first end 210, such as the first end 210, is configured to be a conductive structure, the current may mainly pass through the isolation structure 200 and enter the second electrode 122 of the inner sub-pixel. The isolation structure 200 is located at intervals between the sub-pixels and does not need to be light-transmitting. Therefore, the conductive structure of the isolation structure 200, such as the first end 210, may be manufactured using materials with high conductivity, such as metals, to alleviate or even eliminate the voltage drop problem.

For example, as shown in FIG. 8, the display panel further includes a pixel defining layer 300 located between the substrate 20 and the isolation structure 200. The pixel defining layer 300 includes a plurality of second openings 301 corresponding to the plurality of first openings 201. An orthographic projection of the second opening 301 on the substrate 20 is located within an orthographic projection of corresponding first opening 201 on the substrate 20, and the pixel defining layer 300 is located between the first electrode 121 and the isolation structure 200.

In the embodiment of the present disclosure, positions and an overall shape of the sub-pixels are limited by both the isolation structure and the anode. Therefore, based on the arrangement of the sub-pixel in the embodiments mentioned above, the isolation structure and the anode may be configured to be as follows.

For example, in at least one embodiment of the present disclosure, as shown in FIGS. 1, 4, 5, and 8, the display panel 10 includes an isolation structure 200 located on the substrate 20, and the isolation structure 200 includes a plurality of first openings 201. The plurality of first openings 201 are divided into a plurality of opening groups (all first openings shown in FIG. 5 form one opening group), and each of the plurality of opening groups includes a plurality of first openings 201. The first openings 201 of each of the plurality of opening groups may be classified into a first-kind opening 201a, a second-kind opening 201b, and a third-kind opening 201c. The first-kind opening 201a, the second-kind opening 201b, and the third-kind opening 201c are disposed sequentially from inside to outside. A centroid of the opening group is located in the innermost first-kind opening 201a, and at least one of the second-kind opening 201b and the third-kind opening 201c located on the outer side is a non-closed ring. Therefore, the position and shape of the first opening 201 are roughly the position and shape of the sub-pixel (or the light-emitting device included).

As shown in FIG. 5, in a region where each of the plurality of opening groups is located, the isolation structure 200 includes three annular portions 202a, 202b, 202c, and two connection portions 203a, 203b. The annular portions 202a, 202b, and 202c respectively surround the first-kind opening 201a, the second-kind opening 201b, and the third-kind opening 201c. The connection portions 203a and 203b are respectively located in the gaps corresponding to the second-kind opening 201b and the third-kind opening 201c, and the connection portion 203a is located between the annular portions 202a and 202b to connect the annular portions 202a and 202b. The connection portion 203b is located between the annular portions 202b and 202c to connect the annular portions 202b and 202c.

For example, in at least one embodiment of the present disclosure, as shown in FIGS. 1, 6 to 8, the display panel 10 may include a plurality of first electrodes 121 located on the substrate 20. The first electrodes 121 are divided into a plurality of electrode groups 110, and each of the plurality of electrode groups 110 includes a plurality of first electrodes 121. The first electrodes 121 of each of the plurality of the electrode groups 110 may be classified into an electrode 111, an electrode 112, and an electrode 113. The electrode 111, the electrode 112, and the electrode 113 are disposed sequentially from inside to outside. In each of the electrode groups 110, a centroid of the electrode group 110 is located in the innermost electrode 111, and the electrode 112 and the electrode 113 located on the outer side are closed rings. For example, an orthographic projection of the first opening 201 on the substrate 20 is located within an orthographic projection of the first electrode 121 of corresponding sub-pixel on the substrate 20. Thus, the light-emitting function layer 123 in the sub-pixel may be in contact with the first electrode 121, so that the anode voltage may be applied to each region of the light-emitting function layer 123.

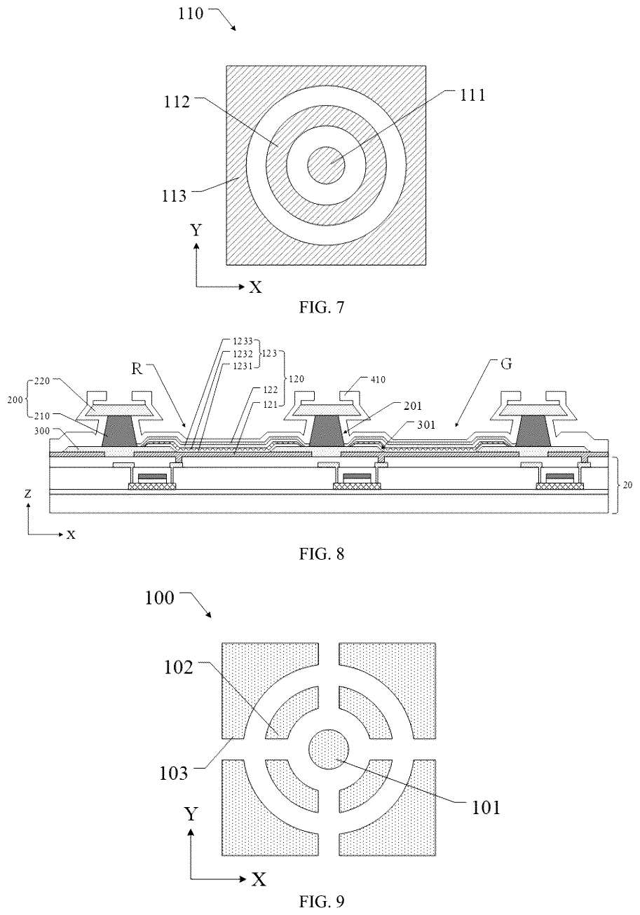

For example, in each sub-pixel, the edge of the first electrode 121 roughly coincides with an outer edge or an inner edge of the adjacent sub-pixel. It means that the edge of the first electrode 121 has a shape substantially same to or matched with that of the outer edge or the inner edge of the adjacent sub-pixel. Specifically, as shown in FIGS. 3 and 7, the edge of the middle sub-pixel is arc-shaped, and correspondingly, the edge of the first electrode 121 included in the middle sub-pixel is arc-shaped.

In the embodiment of the present disclosure, for each pixel unit, the number of sub-pixels including a gap and a quantity of gaps of each sub pixel are not specifically limited, and may be designed based on requirements of an actual process. In the following, several specific embodiments will be provided to illustrate different selections mentioned above, as well as the positions, shapes, and specific settings of other structures involved, such as the isolation structure and the first electrode.

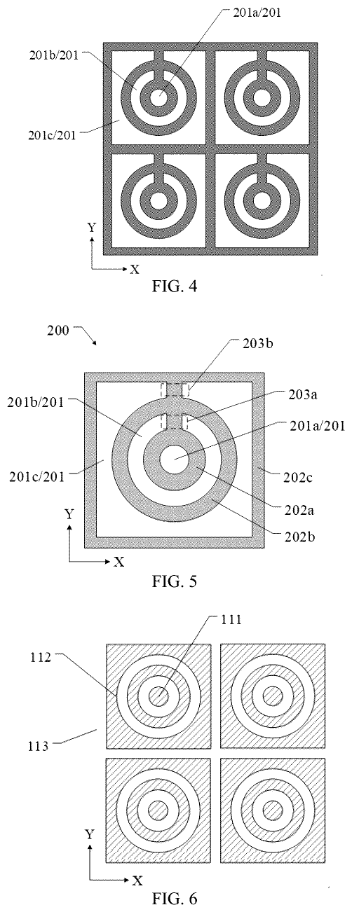

In at least one embodiment of the present disclosure, as shown in FIGS. 2 and 3, excepting for the innermost sub-pixel (the first sub-pixel 101), the remaining sub-pixels (the second sub-pixel 102 and the third sub-pixel 103) are respectively configured to include at least one gap. In this way, the voltage drop difference between any sub-pixels in each pixel unit 100 may be basically ignored, thereby further improving the display effect of the display panel. In addition, accordingly, as shown in FIGS. 4 and 5, in each opening group, except for the innermost first opening 201, the remaining first openings 201 are respectively configured to be a non-closed ring.

For example, in at least one embodiment of the present disclosure, the preset positions of the sub-pixels may be adjusted, so that the centroid of the innermost sub-pixel (the first sub-pixel 101) coincides with the centroid of the pixel unit 100; and/or, the centroid of the outermost sub-pixel coincides with the centroid of pixel unit 100; and/or, the centroid of the ring where outer edges of the outermost sub-pixel and the innermost sub-pixel are located coincides with the centroid of pixel unit 100.

In at least one embodiment of the present disclosure, in each pixel unit 100, the centroid of at least one sub-pixel basically coincides with the centroid of the pixel unit 100. For example, as shown in FIGS. 2 and 3, the centroid of the first sub-pixel 101 completely coincides with the centroid of the pixel unit 100. The centroids of the second sub-pixel 102 and the third sub-pixel 103 are slightly offset than the centroids of the pixel unit 100 and are roughly overlapped, since the second sub-pixel 102 and the third sub-pixel 103 include gaps. In this way, the uniformity of light emission of each sub-pixel in the pixel unit 100 may be improved, thereby further improving the display effect of the display panel. In addition, accordingly, as shown in FIGS. 4 and 5, in each of the opening groups, the centroid of each first opening 201 basically coincides with the centroid of the opening group. As shown in FIGS. 6 and 7, in each of the electrode groups 110, the centroid of each first electrode coincides with the centroid of the electrode group 110.

In the embodiment of the present disclosure, the specific pattern shape of the sub-pixels may be further designed to reduce an offset error between the centroid of the sub-pixels and the pixel unit where the sub-pixels are located.

In at least one embodiment of the present disclosure, as shown in FIGS. 2 and 3, at least one of the sub-pixels in each pixel unit 100 is symmetrical relative to the centroid of the pixel unit 100. In this way, the sub-pixels may be further uniformly distributed around the centroid of pixel unit 100 to further improve the display effect of the display panel. Accordingly, as shown in FIGS. 4 and 5, at least one of the first openings 201 in each opening group is symmetrical relative to the centroid of the opening group.

In at least one embodiment of the present disclosure, as shown in FIGS. 2 and 3, adjacent edges of adjacent sub-pixels coincide with each other, i.e., adjacent edges of adjacent sub-pixels have substantially same or matched shape. Accordingly, as shown in FIGS. 4 and 5, adjacent edges of adjacent first openings 201 coincide with each other. In this way, intervals between adjacent sub-pixels may be reduced to increase a design area of the sub-pixels, thereby improving display brightness.

In some embodiments of the present disclosure, as shown in FIGS. 2 and 3, a shape of the outer edge of the outermost sub-pixel is different from a shape of the inner edge of the outermost sub-pixel. Accordingly, as shown in FIGS. 4 and 5, the shape of the outer edge of the outermost first opening 201 is different from the shape of the inner edge of the outermost first opening 201. Thus, the overall shape of the pixel units may be not limited by the shape of the inner sub-pixel, making it easier to arrange pixel units in the display area to improve pixel-per-inch (PPI) of the pixel units. The inner edge and the outer edge of the “sub pixel” in the present disclosure, when limited, both refer to the part where the sub-pixels effectively emit light.

In other embodiments of the present disclosure, the shape of the outer edge coincides with the shape of the inner edge of the outermost sub-pixel (referring to the embodiment as shown in FIG. 11 below). The shape of the outer edge and the shape of the inner edge of the outermost sub-pixel are substantially same or matched. Accordingly, as shown in FIGS. 4 and 5, the shape of the outer edge coincides with the shape of the inner edge of the outermost first opening 201. Thus, the light-emitting region of the outermost sub-pixel can be uniformly distributed relative to the center of the pixel unit.

In some embodiments of the present disclosure, as shown in FIGS. 2 and 3, the sub-pixels in each of the pixel units 100 are classified into a first sub-pixel 101, a second sub-pixel 102, and a third sub-pixel 103. The first sub-pixel 101 and the third sub-pixel 103 are both symmetrical relative to the centroid of the pixel unit 100. The second sub-pixel 102 is an imaginary axial-symmetric shape and includes a gap. The third sub-pixel 103 includes a plurality of gaps, and a plurality of third sub-pixel blocks (four third sub-pixel blocks shown in FIG. 3) separated by the plurality of gaps. An imaginary symmetry axis of the second sub-pixel 102 passes through the gap of the second sub-pixel 102 and the centroid of the pixel unit 100. Accordingly, as shown in FIGS. 4 and 5, the first openings 201 in each of the opening groups are classified into a first-kind opening 201a, a second-kind opening 201b, and a third-kind opening 201c. The first-kind opening 201a, the second-kind opening 201b, and the third-kind opening 201c are disposed sequentially from inside to outside. The first-kind opening 201a and the third-kind opening 201c are both symmetrical relative to the centroid of the opening group. The second-kind opening 201b is an imaginary axial-symmetric shape and includes a gap. The third-kind opening 201c includes a plurality of gaps and a plurality of third sub-openings separated by the plurality of gaps. An imaginary symmetry axis of the second-kind opening 201b passes through the gap of the second-kind opening 201b and the centroid of the opening group.

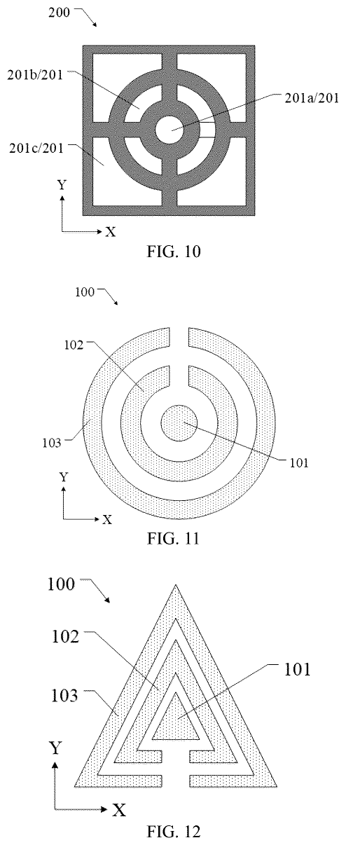

In other embodiments of the present disclosure, as shown in FIG. 9, the first sub-pixel 101, the second sub-pixel 102, and the third sub-pixel 103 are all symmetrical relative to the centroid of the pixel unit 100. The second sub-pixel 102 and the third sub-pixel 103 include a plurality of gaps. The second sub-pixel 102 includes a plurality of second sub-pixel blocks separated by the gaps, and the third sub-pixel 103 includes a plurality of third sub-pixel blocks separated by the gaps. Accordingly, as shown in FIG. 10, the first-kind opening 201a, the second-kind opening 201b, and the third-kind opening 201c are all symmetrical relative to the centroid of the opening group. The second-kind opening 201b and the third-kind opening 201c include a plurality of gaps. The second-kind opening 201b includes a plurality of second sub-openings separated by the gaps, and the third-kind opening 201c includes a plurality of third sub-openings separated by the gaps.

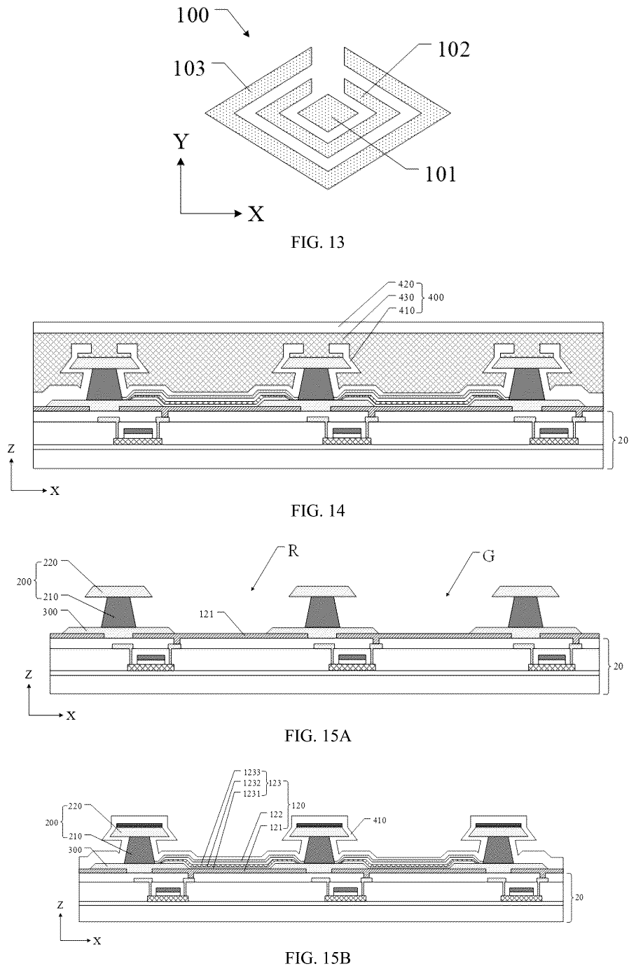

In the embodiment of the present disclosure, a specific shape of the sub-pixel is not limited, as shown in FIGS. 9, 11 to 13. The shape of an edge of the sub-pixel includes at least one of a circle, a triangle, a rectangle, and a parallelogram.

The pattern shapes shown in FIGS. 9, 12, and 13 may help reduce the spacing between the pixel units and improve the PPI of the pixel units.

In at least one embodiment of the present disclosure, as shown in FIG. 8, the display panel may further include a protective layer 410, and the protective layer 410 at least covers the light-emitting device 120 to protect the film layer of the light-emitting device 120 during the preparation process of the display panel. The light-emitting devices 120 with different light emitted are independently prepared, but the film layers (such as the light-emitting unit) in each light-emitting device 120 are vapor deposited as a full surface on the display panel during vapor deposition. For example, the light-emitting devices 120 are classified into light-emitting devices that respectively emit red light (R, the first sub-pixel for example), green light (G, the second sub-pixel for example), and blue light (B, the third sub-pixel for example). During the preparation process, the light-emitting devices R, G, and B are sequentially prepared. When preparing the light-emitting device R, a light-emitting device R in each of the plurality of first openings, and a protective layer 410 is prepared on the display panel to cover the light-emitting device G. Then, the protective layer 410 in some first openings (used for forming light-emitting devices G and B in the final product), as well as the cathode and light-emitting unit of the light-emitting device R, are removed. In this process, the protective layer 410 is used for protecting the light-emitting devices R in other first openings. Based on this method, the light-emitting devices G and B are sequentially prepared, and finally the protective layer 410 is formed as shown in FIG. 8.

In at least one embodiment of the present disclosure, as shown in FIG. 14, the display panel may include an encapsulation layer 400 that covers the display function layer, and the protective layer 410 may be one of the film layers in the encapsulation layer 400. Specifically, the encapsulation layer 400 includes a first inorganic encapsulation layer (the protective layer 410) and a second inorganic encapsulation layer 420 stacked sequentially on the display function layer, as well as an organic encapsulation layer 430 located between the first inorganic encapsulation layer (the protective layer 410) and the second inorganic encapsulation layer 420. The organic encapsulation layer 430 is used to flatten the surface of the display panel to facilitate the setting of structures such as a touch function structure, an optical film, a cover plate, and so on, on the side, from which the light emits, of the display panel.

In the following, the preparation process of the display panel shown in FIG. 8 will be described with reference to FIGS. 15A to 15D.

As shown in FIG. 15A, providing a substrate 20 is provided, and a plurality of first electrodes 121 are formed on the substrate 20 and arranged in array. An insulating material film layer (such as an inorganic material film layer) is deposited on the substrate 20 after the first electrodes 121 are formed. A first end 210 and a second end 220 are formed on the display panel, where a first opening and a second opening (not shown in the figure and may be referred to in the accompanying drawings mentioned above) are formed. A composition process is performed on the insulation material film layer to form a pixel defining layer 300 (the planar shape of which is grid-like), where the pixel defining layer 300 covers the intervals between adjacent first electrodes 121, therefore, a planar shape of the pixel defining layer 300 is grid-shape.

In the embodiment of the present disclosure, the composition process may be a photolithography composition process. For example, the composition process may include: coating photoresist on a structural layer to be patterned; exposing the photoresist with a mask plate; developing the exposed photoresist to obtain a photoresist pattern; etching the structural layer with the photoresist pattern (both dry and wet etching are available); and optionally removing the photoresist pattern. In a case where a material of the structural layer (such as the photoresist pattern 500 below) includes photoresist, the structural layer may be directly exposed through a mask plate to form a desired pattern.

As shown in FIG. 15B, a light-emitting function layer 123 and a second electrode 122 are vapor deposited on the substrate 20 to form a light-emitting device 120 in each first opening of the isolation structure 200. A mask plate is not used during the process of vapor deposition, so the material of the vapor deposition will also deposit on the second end 220 and in the second opening. Then a protective layer 410 is deposited to cover the light-emitting device 120. The protective layer 410 will cover the entire display area during this step. For example, a light-emitting layer 1232 in the vapor deposited light-emitting function layer 123 may emit red light (R), that is, in this step, a light-emitting device 120 with red light emitted is formed in each first opening of the isolation structure 200.

As shown in FIG. 15C, a photoresist is formed on the substrate 20 after the protective layer 410 is formed. And then the photoresist is patterned to form a photoresist pattern 500. The photoresist pattern 500 only covers a part of the first opening of the isolation structure 200 (the corresponding first opening with red light emitted when the display panel is prepared).

As shown in FIG. 15D, a surface of the display panel is etched with the photoresist pattern 500 as a mask to remove the protective layer 410, the second electrode 122, and the light-emitting function layer 123 covered by the photoresist pattern 500. Then, the remaining photoresist pattern 500 is removed.

Steps shown in FIGS. 15A to 15D above are performed repeatedly to respectively form light-emitting devices 120 with green light and blue light emitted in the other first openings, and a display panel is formed as shown in FIG. 8.

In some embodiments of the present disclosure, some film layers in the light-emitting unit, such as the light-emitting layer, may be prepared by non vapor deposition methods such as inkjet printing, and specifically, the methods may be selected based on the material of these film layers. For example, in a case where these film layers are high resolution materials and are not suitable for vapor deposition, inkjet printing may be used for preparation.

For example, in the embodiment of the present disclosure, the display panel may further include an encapsulation layer covering the display function layer. The encapsulation layer is configured to isolate the light-emitting device in the display function layer and has a planarization function to facilitate providing a touch function layer, a polarizer, a lens layer, a cover plate, and other functional structures on the encapsulation layer. For example, the encapsulation layer may include a first inorganic encapsulation layer, an organic encapsulation layer, and a second inorganic encapsulation layer sequentially stacked on the display function layer. The first inorganic encapsulation layer and second inorganic encapsulation layer have high density to isolate water and oxygen, and the organic encapsulation layer has a larger thickness and planarization function. For example, where the protective layer mentioned before is set in the display panel, the protective layer may be independently set between the first encapsulation layer and the display function layer, or can serve as the first inorganic encapsulation layer.

For example, in the embodiment of the present disclosure, the display device may be any product or component with display function, such as a television, a digital camera, a mobile phone, a watch, a tablet, a laptop, a navigation device, and so on.

The above description is merely a preferred embodiment of this specification and is not intended to limit it. Any modifications, equivalent substitutions, and so on, made within the spirit and principles of this specification shall be included within the protection scope of this specification.

What is claimed is:

1. A display panel, comprising a plurality of pixel units, wherein each of the plurality of pixel units comprises a plurality of sub-pixels emitting light of different colors,
in each of the plurality of pixel units, the plurality of sub-pixels comprise a first sub-pixel, a second sub-pixel, and a third sub-pixel arranged sequentially from inside to outside and respectively in a surrounding manner, and a centroid of the pixel unit is located in the first sub-pixel, and
at least one of the second sub-pixel and the third sub-pixel is configured to be a non-closed ring comprising at least one gap, wherein the gap communicates with an inner side and an outer side of the at least one of the second sub-pixel and the third sub-pixel.

2. The display panel according to claim 1, wherein the second sub-pixel and the third sub-pixel are configured to comprise at least one gap.

3. The display panel according to claim 1, wherein in each of the plurality of pixel units, at least one of centroids of the first sub-pixel, the second sub-pixel, and the third sub-pixel coincides with the centroid of the pixel unit.

4. The display panel according to claim 3, further comprising a substrate and an isolation structure located on the substrate, wherein
the isolation structure comprises a plurality of first openings, the plurality of first openings are configured to confine the sub-pixel, the sub-pixel comprises a first electrode, a light-emitting function layer, and a second electrode sequentially stacked on the substrate, and the light-emitting function layer of the sub-pixel is located in the corresponding first opening,
an orthographic projection of the isolation structure on the substrate is located at intervals and the gaps between orthographic projections of the sub-pixels on the substrate, the isolation structure comprises a first end facing the substrate and a second end facing away from the substrate, and an orthographic projection of the first end on the substrate is located within an orthographic projection of the second end on the substrate, and
the second electrode of the sub-pixel is located in the corresponding first opening, the second electrode is connected to the first end, and the first end is a conductive structure.

5. The display panel according to claim 4, wherein
first electrodes of the second sub-pixel and the third sub-pixel are closed rings, an orthographic projection of the first opening on the substrate is located within an orthographic projection of the first electrode of the corresponding sub-pixel located in the first opening on the substrate, and an edge of the first electrode coincides with an outer edge or an inner edge of an adjacent sub-pixel.

6. The display panel according to claim 3, wherein in each of the plurality of pixel units, at least one of the sub-pixels is symmetrical relative to the centroid of the pixel unit.

7. The display panel according to claim 6, wherein
edges of adjacent sub-pixels coincide with each other;
a shape of an outer edge of an outermost sub-pixel coincides with to a shape of an inner edge of the outermost sub-pixel, or
the shape of the outer edge of the outermost sub-pixel is different from the shape of the inner edge of the outermost sub-pixel;
a shape of an edge of the sub-pixel comprises at least one of a circle, a triangle, a rectangle, and a parallelogram.

8. The display panel according to claim 6, wherein
the first sub-pixel and the third sub-pixel are symmetrical relative to the centroid of the pixel unit, the second sub-pixel has an imaginary axial-symmetric shape, the second sub-pixel comprises the gap, the third sub-pixel comprises a plurality of the gaps, the third sub-pixel comprises a plurality of third sub-pixel blocks separated by the plurality of gaps, and an imaginary symmetry axis of the second sub-pixel passes through the gap of the second sub-pixel and the centroid of the pixel unit; or
the first sub-pixel, the second sub-pixel, and the third sub-pixel are symmetrical relative to the centroid of the pixel unit, and the second sub-pixel and the third sub-pixel comprise a plurality of the gaps, the second sub-pixel comprises a plurality of second sub-pixel blocks separated by the gaps, and the third sub-pixel comprises a plurality of third sub-pixel blocks separated by the gaps.

9. A display panel, comprising a substrate and an isolation structure located on the substrate, wherein the isolation structure comprises a plurality of opening groups, and each of the plurality of opening groups comprises a plurality of first openings, and
in at least one of the plurality of opening groups, a centroid of the opening group is located in an innermost first opening, the plurality of first openings are disposed sequentially from inside to outside, and at least one of the first openings located on an outer side of the innermost first opening is a non-closed ring with a gap.

10. The display panel according to claim 9, wherein in each of the plurality of opening groups, the first openings excepting for the innermost first opening are respectively configured to be a non-closed ring with the gap.

11. The display panel according to claim 10, wherein the isolation structure comprises a plurality of connection portions and a plurality of annular portions respectively surrounding the first openings, the connection portions are located between the annular portions, and an orthographic projection of the connection portion on the substrate is located in an orthographic projection of the gap on the substrate, and
the adjacent annular portions are connected to each other through the connection portions.

12. The display panel according to claim 9, wherein in each of the plurality of opening groups, a centroid of each first opening coincides with the centroid of the opening group.

13. The display panel according to claim 12, further comprising a plurality of sub-pixels defined by the plurality of first openings, wherein
the plurality of sub-pixels defined by each of the plurality of first openings comprise a first sub-pixel, a second sub-pixel, and a third sub-pixel, and the first sub-pixel, the second sub-pixel, and the third sub-pixel are disposed sequentially from inside to outside and respectively in a surrounding manner,
each of the plurality of sub-pixels comprises a first electrode, a light-emitting function layer, and a second electrode sequentially stacked on the substrate, and the light-emitting function layer of the sub-pixel is located in the corresponding first opening,
the isolation structure comprises a first end facing the substrate and a second end facing away from the substrate, and an orthographic projection of the first end on the substrate is located within an orthographic projection of the second end on the substrate, and
the second electrode of the sub-pixel is located in the corresponding first opening, the second electrode is connected to the first end, and the first end is a conductive structure.

14. The display panel according to claim 13, wherein
the first electrodes of the second sub-pixel and the third sub-pixel are closed rings, an orthographic projection of the first opening on the substrate is located within an orthographic projection of the first electrode of the sub-pixel located in the first opening on the substrate, and
in each of the plurality of sub-pixels, an edge of the first electrode coincides with an outer edge or an inner edge of an adjacent sub-pixel.

15. The display panel according to claim 12, wherein in each of the plurality of opening groups, at least one of the first openings is symmetrical relative to the centroid of the opening group.

16. The display panel according to claim 15, wherein
adjacent edges of adjacent first openings coincide with each other;
a shape of an outer edge of an outermost first opening is coincides with a shape of an inner edge of the outermost first opening, or
the shape of the outer edge of the outermost first opening is different from the shape of the inner edge of the outermost first opening;
a shape of an edge of the first opening comprises at least one of a circle, a triangle, a rectangle, and a parallelogram.

17. The display panel according to claim 15, wherein the plurality of first openings of each of the plurality of opening groups comprise a first-kind opening, a second-kind opening, and a third-kind opening, and the first-kind opening, the second-kind opening, and the third-kind opening are disposed sequentially from inside to outside, and
the first-kind opening and the third-kind opening are symmetrical relative to the centroid of the opening group, the second-kind opening has an imaginary axial-symmetric shape, the second-kind opening comprises a gap, the third-kind opening comprises a plurality of gaps, the third-kind opening comprises a plurality of third sub-openings separated by the gaps, and an imaginary symmetry axis of the second-kind opening passes through the gap of the second-kind opening and the centroid of the opening group; or
the first-kind opening, the second-kind opening, and the third-kind opening are symmetrical relative to the centroid of the opening group, and the second-kind opening and the third-kind opening comprise a plurality of gaps, the second-kind opening comprises a plurality of second sub-openings separated by the gaps, and the third-kind opening comprises a plurality of third sub-openings separated by the gaps.

18. A display panel, comprising a substrate and a plurality of first electrodes located on the substrate, wherein the plurality of first electrodes are divided into a plurality of electrode groups, and each of the plurality of electrode groups comprises a plurality of first electrodes, and
in each of the plurality of electrode groups, a centroid of the electrode group is located in an innermost first electrode, the first electrodes are disposed sequentially from inside to outside, and the first electrodes located on an outer side of the innermost first electrode are closed rings.

19. The display panel according to claim 18, further comprising a light-emitting function layer and a second electrode stacked on each of the plurality of first electrodes, wherein
the first electrode, the light-emitting function layer, and the second electrode stacked in layers forming a sub-pixel, and the sub-pixels corresponding to the plurality of first electrodes of a same electrode group forming a pixel unit,
the sub-pixels corresponding to each of the plurality of electrode groups comprise a first sub-pixel, a second sub-pixel, and a third sub-pixel, and the first sub-pixel, the second sub-pixel, and the third sub-pixel are disposed sequentially from inside to outside,
at least one of the second sub-pixel and the third sub-pixel is configured to be a non-closed ring with at least one gap, and the gap communicates with an inner side and an outer side of the at least one of the second sub-pixel and the third sub-pixel, and
in each of the plurality of electrode groups, a centroid of each of the first electrodes coincides with the centroid of the electrode group.

20. The display panel according to claim 19, further comprising an isolation structure located on the substrate, wherein the isolation structure comprises a plurality of first openings respectively corresponding to the plurality of first electrodes, the light-emitting function layer of the sub-pixel is located in the corresponding first opening, and an orthographic projection of the first opening on the substrate is located within an orthographic projection of the corresponding first electrode on the substrate, and
orthographic projections of intervals between the first electrodes on the substrate coincide with an orthographic projection of the isolation structure on the substrate, or are located within the orthographic projection of the isolation structure on the substrate, and in each of the plurality of sub-pixels, an edge of the first electrode coincides with an outer edge or an inner edge of an adjacent sub-pixel,
the isolation structure comprises a first end facing the substrate and a second end facing away from the substrate, and an orthographic projection of the first end on the substrate is located within an orthographic projection of the second end on the substrate, and
the second electrode of the sub-pixel is located in the corresponding first opening, the second electrode is connected to the first end, and the first end is a conductive structure.
